(19) United States
(12) Patent Application Publication
(10) Pub. No.: US 2003/0188848 A1
(43) Pub. Date: Oct. 9, 2003

(54) Complex heat-radiator

(76) Inventor: Yu-Chen Kuo, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/117,177

(22) Filed: Apr. 8, 2002

(51) Int. Cl. F28F 7/00; F28F 13/18; F28F 19/02; H05K 7/20; H01L 23/34

(52) U.S. Cl. 165/80.3; 165/133; 165/185; 361/704; 257/722

(57) ABSTRACT

A complex heat-radiator including a heat conductor made of a material with high thermal conductivity such as copper, and a heat-radiating body made of a material with better heat-radiation efficiency than the heat conductor, such as aluminum. The heat-radiating body includes a heat-contacting board having a heat-contacting face overlaid on a heat source. Multiple projecting heat conductive fins are formed on the heat-contacting board. The heat-radiating body encloses and covers the heat conductive fins of the heat conductor. The heat generated by the heat source can be quickly conducted through the heat conductor with better thermal conductivity to the heat-radiating body. Then, the heat-radiating body with better heat-radiation efficiency quickly radiates the heat to outer side to be quickly dissipated.

### BACKGROUND OF THE INVENTION

1. Field of the Invention

The present invention is related to a complex heat-radiator in which a heat conductor with higher thermal conductivity is used as a heat-contacting medium. Multiple projecting heat conductive fins are formed on the heat conductor, which fins extend into and over a heat-radiating body with better heat-radiation efficiency.

2. Description of the Prior Art

FIG. 8 shows an existent heat-radiator for a chip. The heat-radiator includes a heat-radiator main body 3 made of aluminum material by various mechanical processing procedures, a connecting face 31 positioned on a certain portion of the main body 3 and a heat conductive plate 4 fixed on the connecting face 31 by a certain measure. The heat conductive plate 4 has a thermal conductivity greater than that of the aluminum-made main body 3. The heat conductive plate 4 with higher thermal conductivity is attached to a heat source, whereby the heat of the heat source can be quickly conducted through the heat conductive plate 4 to the main body 3. Then the heat is radiated to outer side by the main body 3 and quickly dissipated.

In the above structure, the heat conductive plate 4 is a sheet attached to the bottom of the main body 3 for quickly conducting the heat of the heat source to the main body 3. However, the heat is conducted at high efficiency only on a border portion of the main body 3 near the heat conductive plate 4. When conducted through the main body 3 itself, the heat conducting speed still depends on the main body's own thermal conductivity. That is, it takes a long time to conduct the heat from the border of the main body 3 to the distal heat-radiating fins of the main body 3. The longer the distance is, the longer the cost time is. Accordingly, the heat can be hardly quickly conducted over the main body 3 and a great amount of heat will accumulate in the border of the main body 3 adjacent to the heat conductive plate 4. As a result, the heat cannot be radiated on a large area and the heat-radiation efficiency will be lowered.

### SUMMARY OF THE INVENTION

It is therefore a primary object of the present invention to provide a complex heat-radiator including a heat conductor made of a material with high thermal conductivity such as copper, and a heat-radiating body made of a material with better heat-radiation efficiency than the heat conductor, such as aluminum. The heat-radiating body includes a heat-contacting board having a heat-contacting face overlaid on a heat source. Multiple projecting heat conductive fins are formed on the heat-contacting board. The heat-radiating body encloses and covers the heat conductive fins of the heat conductor. The heat generated by the heat source can be quickly conducted through the heat conductor with better thermal conductivity to the heat-radiating body. Then, the heat-radiating body with better heat-radiation efficiency quickly radiates the heat to outer side to be quickly dissipated.

The present invention can be best understood through the following description and accompanying drawings wherein:

### BRIEF DESCRIPTION OF THE DRAWINGS

FIG. 1 is a perspective view of a first embodiment of the present invention;

FIG. 2 is a sectional view taken along line 2-2 of FIG. 1;

FIG. 3 shows the heat conduction state of the first embodiment of the present invention;

FIG. 4 is a perspective view of a second embodiment of the present invention;

FIG. 5 is a sectional view taken along line 5-5 of FIG. 4;

FIG. 6 shows the heat conduction state of the second embodiment of the present invention;

FIG. 7 is an enlarged view of a part of the second embodiment of the present invention, in which the heat conductor is separated from the heat-radiating body; and

FIG. 8 is a perspective view of a conventional heat-radiator, in which the heat conductive plate is attached to the heat-radiator main body.

### DETAILED DESCRIPTION OF THE PREFERRED EMBODIMENTS

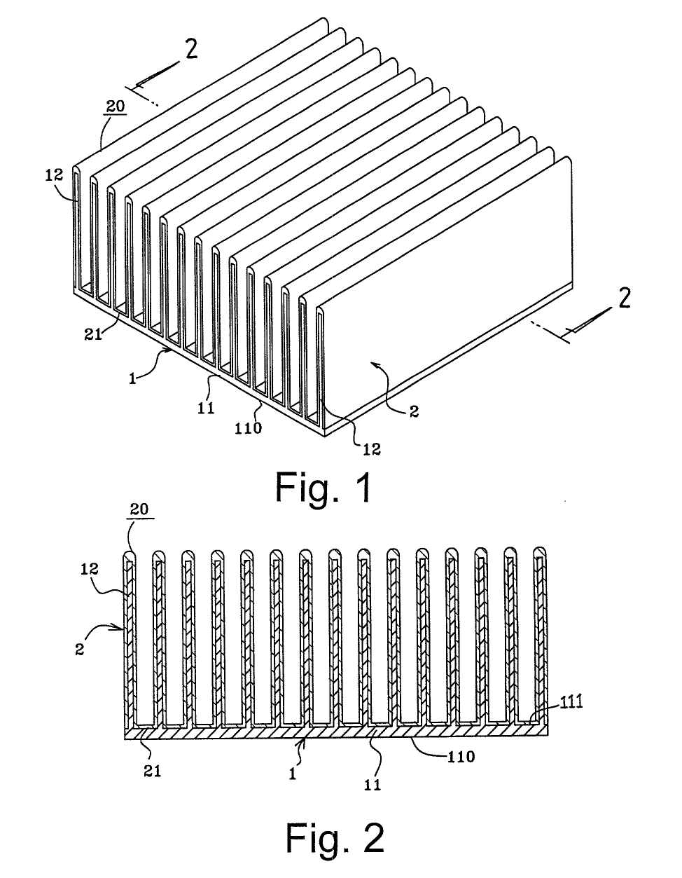

Please refer to FIGS. 1, 2 and 3. The complex heat-radiator of the present invention includes a heat conductor 1 overlaid on a heat source H and made of a material with high thermal conductivity such as copper, and a heat-radiating body 2 made of a material with better heat-radiation efficiency than the heat conductor 1, such as aluminum. The heat-radiating body 2 tightly encloses and covers the heat conductor 1. The heat generated by the heat source H can be quickly conducted through the heat conductor 1 with better thermal conductivity over the heat-radiating body 2. Then, the heat-radiating body 2 with better heat-radiation efficiency quickly radiates the heat to outer side to be quickly dissipated.

The heat conductor of the present invention can be made of a material with high thermal conductivity such as copper. Referring to FIGS. 1, 2 and 3, the heat conductor 1 includes a heat-contacting board 11 having a heat-contacting face 110 and a heat-radiating face 111 opposite to the heat-contacting face 110. The heat-contacting face 110 is overlaid on a heat source. Multiple projecting heat conductive fins 12 are formed on the heat-radiating face 111 of the heat-contacting board 11.

The heat conductor 1 can be made by drawing, injection molding or other measure. The heat conductor 1 can be rectangular, triangular, polygonal or circular.

The heat-radiating body 2 can be made of aluminum or any other material having better heat-radiation efficiency.

In manufacturing, the heat conductor 1 is first formed by drawing. Then the heat conductor 1 is placed in a mold for drawing the heat-radiating body 2. When drawing the heat-radiating body 2, the heat conductor 1 is tightly enclosed and covered by the heat-radiating body 2. The bottom of the heat-radiating body 2 is tightly attached to the heat-contacting board 11 of the heat conductor 1. In addition, the heat-radiating body 2 surrounds the respective heat conductive fins 12 of the heat conductor 1. Therefore, heat-radiating fins 20 containing therein heat conductive fins 12 are formed. Alternatively, the present invention can be made by other measure such as casting.

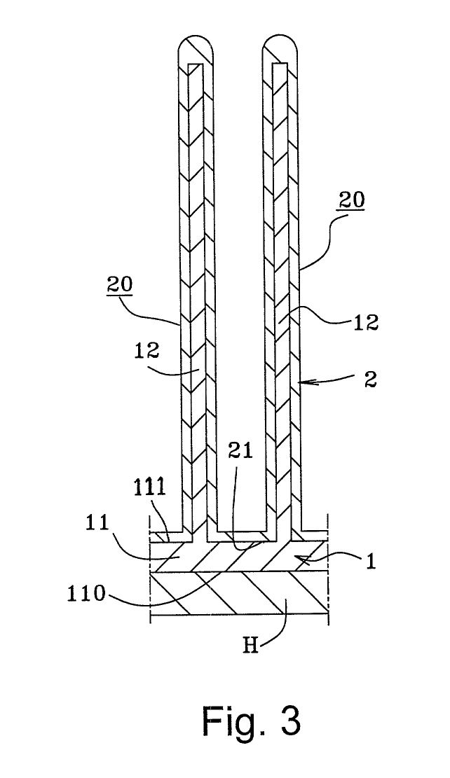

Referring to FIG. 3, in the complex heat-radiator of the present invention, the heat conductive fins 12 extend into and over the heat-radiating body 2. Therefore, when heat conductor 1 takes the heat from the heat source H, the heat can be quickly conducted through the respective heat conductive fins 12 to every parts of the heat-radiating body 2 adjacent to the heat conductive fins 12. Accordingly, the heat will not accumulate on the contacting faces of the heat conductor and heat-radiating body as in the conventional heat-radiator. Therefore, the heat radiation efficiency of the heat-radiator is enhanced.

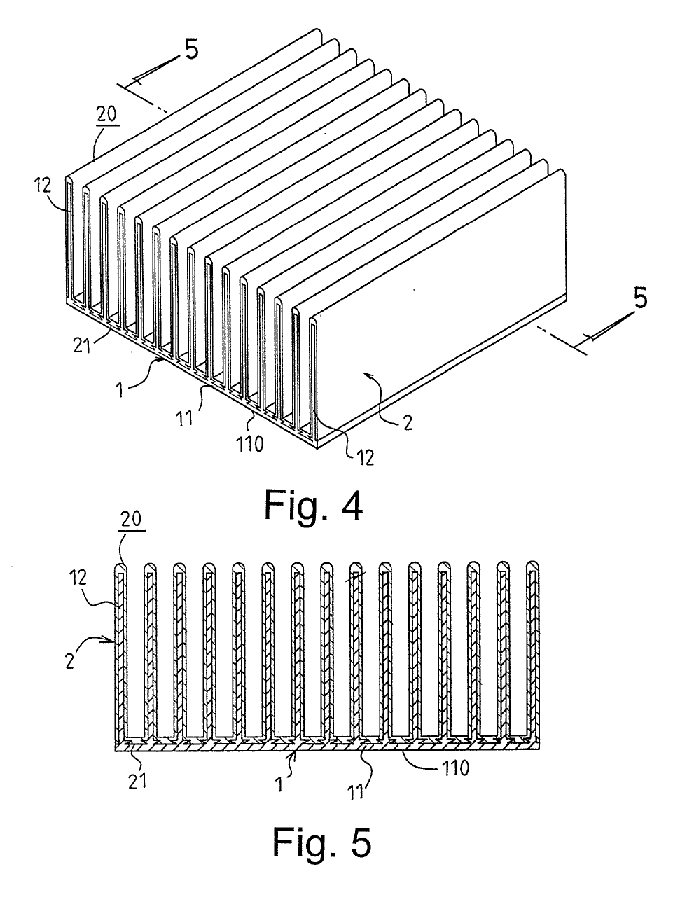

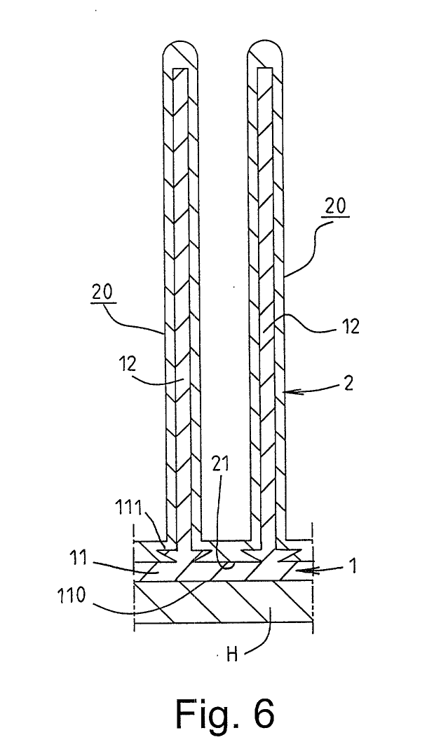

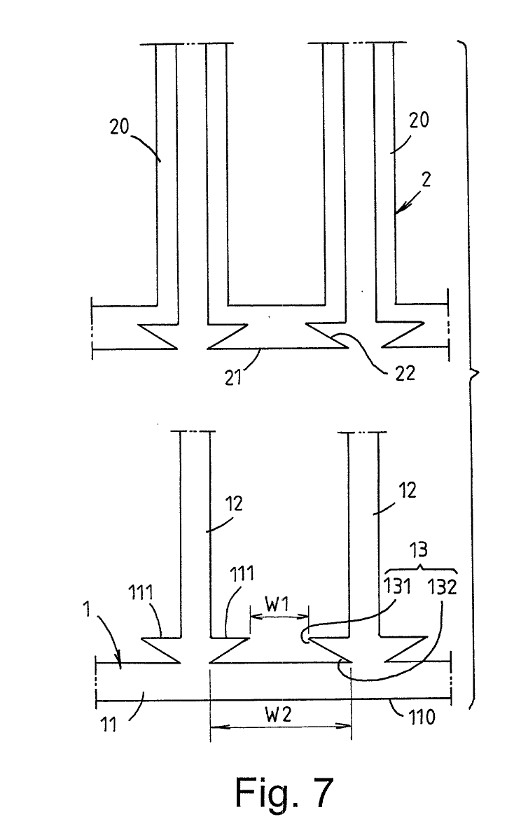

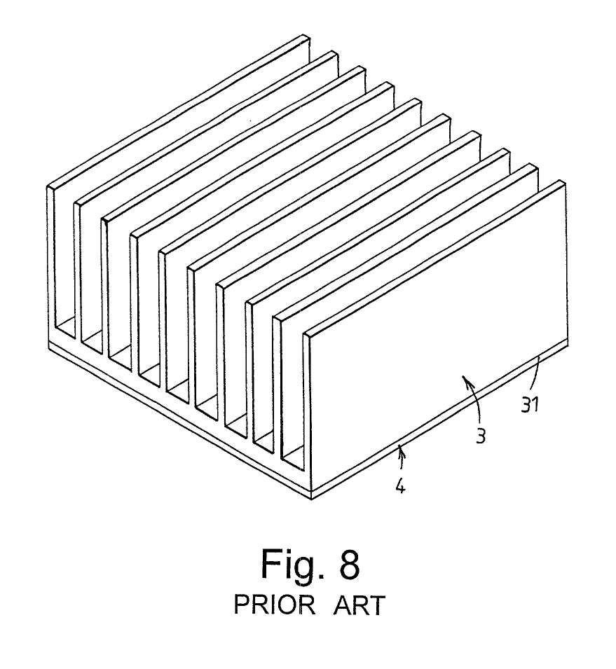

Referring to FIGS. 4 to 7, the heat-radiating face 111 between the heat conductive fins 12 can be formed with connecting channels 13. Each connecting channel 13 includes an opening 131 and a channel section 132. The opening 131 communicates with the heat-radiating face 111 between the heat conductive fins 12 and has a first width W1. The channel section 132 is adjacent to the opening 131 and has a second width W2 which is larger than the first width W1. In addition, the bottom 21 of the heat-radiating body 2 is formed with a connecting projection 22 corresponding to the connecting channel 13. The connecting projection 22 is snugly fully mated with the connecting channel 13, whereby the heat conductor 1 and the heat-radiating body 2 are tightly associated without detaching from each other.

The above embodiments are only used to illustrate the present invention, not intended to limit the scope thereof. Many modifications of the above embodiments can be made without departing from the spirit of the present invention.

What is claimed is:

1. A complex heat-radiator comprising:
(a) a heat conductor including a heat-contacting board having a heat-contacting face overlaid on a heat source, multiple projecting heat conductive fins being formed on the heat-contacting board; and
(b) a heat-radiating body surrounding the respective heat conductive fins of the heat conductor to form heat-radiating fins containing therein the heat conductive fins, the heat conductor having a thermal conductivity higher than that of the heat-radiating body, while the heat-radiating body having a heat-radiation efficiency better than that of the heat conductor.

2. The complex heat-radiator as claimed in claim 1, wherein the heat conductor is made of copper, while the heat-radiating body is made of aluminum.

3. The complex heat-radiator as claimed in claim 1, wherein the bottom of the heat-radiating body is attached to the heat-contacting board of the heat conductor.

4. A complex heat-radiator comprising:
(a) a heat conductor including a heat-contacting board having a heat-contacting face and a heat-radiating face opposite to the heat-contacting face, the heat-contacting face being overlaid on a heat source, multiple projecting heat conductive fins being formed on the heat-radiating face of the heat-contacting board, the heat-radiating face between the heat conductive fins being formed with connecting channels, each connecting channel including an opening communicating with the heat-radiating face between the heat conductive fins and having a first width, and a channel section being adjacent to the opening and having a second width, the second width being larger than the first width; and
(b) a heat-radiating body surrounding the respective heat conductive fins of the heat conductor to form heat-radiating fins containing therein the heat conductive fins, the heat conductor having a thermal conductivity higher than that of the heat-radiating body, while the heat-radiating body having a heat-radiation efficiency better than that of the heat conductor, the bottom of the heat-radiating body being formed with a connecting projection corresponding to the connecting channel, the connecting projection being fully mated with the connecting channel to tightly associate the heat conductor and the heat-radiating body with each other.

5. The complex heat-radiator as claimed in claim 4, wherein the heat conductor is made of copper, while the heat-radiating body is made of aluminum.

6. The complex heat-radiator as claimed in claim 4, wherein the bottom of the heat-radiating body is attached to the heat-contacting board of the heat conductor.
